(19) United States
(12) Patent Application Publication
(10) Pub. No.: US 2014/0305484 A1
(43) Pub. Date: Oct. 16, 2014

(54) THERMOELECTRIC CONVERSION MATERIAL

(71) Applicant: SOGANG UNIVERSITY RESEARCH FOUNDATION, Seoul (KR)

(72) Inventor: Myung-Hwa Jung, Seoul (KR)

(73) Assignee: SOGANG UNIVERSITY RESEARCH FOUNDATION, Seoul (KR)

(21) Appl. No.: 14/048,401

(22) Filed: Oct. 8, 2013

(30) Foreign Application Priority Data
Apr. 15, 2013 (KR) 10-2013-0041010

(51) Int. Cl. H01L 35/16; H01L 35/34

(52) U.S. Cl. CPC H01L 35/16; H01L 35/34
USPC 136/238; 252/62.3 T

(57) ABSTRACT

Provided is a thermoelectric conversion material which is composed of Bi₂₋ₓMnₓSe₃, is single-crystalline, and has a p-type carrier.

### CROSS-REFERENCE TO RELATED APPLICATIONS

This U.S. non-provisional patent application claims priority under 35 U.S.C. §119 to Korea Patent Application No. 10-2013-0041010, filed on Apr. 15, 2013, the entirety of which is hereby incorporated by reference.

### BACKGROUND OF THE INVENTION

1. Field of the Invention

The present invention relates thermoelectric conversion materials and, more particularly, to Mn-doped Bi₂₋ₓMnₓSe₃ that is single-crystalline and has a p-type carrier.

2. Description of the Related Art

Conventionally, BiSe-based materials have been used as thermoelectric conversion materials.

### SUMMARY OF THE INVENTION

Embodiments of the present invention provide a thermal conversion material having a high Seebeck coefficient and a thermoelectric element.

A thermoelectric conversion material according to an embodiment of the present invention may be composed of Bi₂₋ₓMnₓSe₃, be single-crystalline, and have a p-type carrier.

In an exemplary embodiment, 0.05<x<0.2.

In an exemplary embodiment, the thermoelectric conversion material may be aligned with c-axis.

A thermoelectric element according to an embodiment of the present invention may include a first thermoelectric material which is composed of is composed of Bi₂₋ₓMnₓSe₃, is single-crystalline, and has a p-type carrier; and a second thermoelectric material which is connected in series to the first thermoelectric material and has an n-type carrier.

In an exemplary embodiment, 0.05<x<0.2, and the first and second thermoelectric materials may be aligned with c-axis.

In an exemplary embodiment, the second thermoelectric material may be n-type and be composed of Bi_{2-y}Mn_{y}Se₃ (0≦y≦0.05).

The thermoelectric conversion material may be produced by a method which may include sequentially storing Bi, Mn, and Se grains in a quartz ampoule according to a stoichiometric ratio to sequentially store Bi, Mn, and Se; heating the quartz ampoule storing Se, Mn, and Bi in a furnace to a temperature of 850 degrees centigrade over 12 hours; keeping the quartz ampoule at a temperature of 850 degrees centigrade for an hour; slowly cooling the quartz ampoule to a temperature of 620 degrees centigrade over 46 hours; taking out the ampoule from the furnace while keeping the ampoule at the temperature of 620 degrees centigrade; and immersing the quartz ampoule in cooling water to be quenched. The produced material may be composed of Bi₂₋ₓMnₓSe₃, be single-crystalline, and have a p-type carrier.

### BRIEF DESCRIPTION OF THE DRAWINGS

The above and other objects, features and advantages of the present invention will become more apparent from the following detailed description made with reference to the accompanying drawings. In the drawings:

FIG. 1 shows XRD data of Mn-doped Bi₂₋ₓMnₓSe₃ single crystal according to an embodiment of the present invention;

FIG. 2 shows XAS data of Mn-doped Bi₂₋ₓMnₓSe₃ single crystal (x=0.15) according to an embodiment of the present invention;

FIG. 3 shows data indicating a Seebeck coefficient of Mn-doped Bi₂₋ₓMnₓSe₃ single crystal (x=0.03, x=0.15) according to an embodiment of the present invention;

FIG. 4 shows data indicating temperature-dependent resistivity according to an embodiment of the present invention;

FIG. 5 shows a thermoelectric element 100 according to an embodiment of the present invention;

FIG. 6 shows a thermoelectric element according to an embodiment of the present invention;

FIG. 7A shows data indicating an open voltage measured using the thermoelectric element in FIG. 6;

FIG. 7B shows data indicating short-circuit current measured using the thermoelectric element in FIG. 6; and

FIG. 7C shows data indicating maximum power calculated using the thermoelectric element in FIG. 6.

### DETAILED DESCRIPTION OF EMBODIMENTS

Embodiments of the present invention will now be described more fully hereinafter with reference to accompanying drawings.

The article entitled “Simple tuning of carrier type in topological insulator Bi₂Se₃ by Mn doping”, Choi et al., Applied Physics Letters, 101, 152103 (2012) is hereby incorporated as a part of this invention.

Energy and the environment are the most important issues to humankind today. Researches continue to be conducted on new energy sources that can exhibit the same efficiency as fossil fuels and replace the entire industry depending on fossil fuels. Energy conversion technology using thermoelectric conversion materials has been used in thermoelectric cooling apparatuses and thermoelectric power generators for converting thermal energy to electric energy. A thermoelectric cooling apparatus has been used to cool a small area such as a computer chip and an infrared sensor, and a thermoelectric power generator has been used in power stations or artificial satellites.

Currently, Bi₂Te₃ and Bi₂Se₃-based alloys are most widely used as thermoelectric materials. In case of Bi₂Te₃, a carrier may be converted to an electron or a hole by adjusting a composition ratio of Bi and Te.

In Bi₂Se₃, Se vacancies are dominant. Therefore, Bi₂Se₃ has n-type charge carriers. It has been reported that in case of Bi₂Se₃, a carrier may be converted to an electron or a hole by calcium (Ca) or Magnesium (Mg) doping. However, a function for serving as a thermoelectric element has not been exhibited.

According to an embodiment of the present invention, conductivity type of Bi₂₋ₓMnₓSe₃ changed from an n-type thermoelectric material to a p-type thermal material according to Mn doping concentration. In addition, the p-type thermoelectric material had a high Seebeck coefficient and a high carrier concentration.

According to an embodiment of the present invention, Mn-doped Bi₂Se₃ may be formed by a thermoelectric power generating element or a thermoelectric cooling element. The estimated amount of power was calculated through a voltage, current, and resistance of the thermoelectric power generating element.

Seebeck effect, Peltier effect, and Thompson effect are representative thermoelectric phenomena. In 1821, Thomas Johann Seebeck discovered that current or a voltage is generated according to a temperature difference when different temperatures are applied to a junction between different conductive materials.

V=SΔT Equation 1(1)

wherein V represents a thermoelectric voltage, ΔT represents a temperature gradient applied to both ends of a thermoelectric element, and S represents a Seebeck coefficient.

The Peltier effect is an opposite of the Seebeck effect, where heat is released or absorbed at a junction of two conductive materials when current or a voltage is applied. The Thompson effect is a phenomenon where heat is absorbed or released at both ends of a single conductor when a potential difference is applied to both the ends of the single conductor.

In general, a metal possesses a very small Seebeck coefficient of several μV/K and a semiconductor possesses a Seebeck coefficient of hundreds of μV/K. A dimensionless figure of merit (ZT) is used as an index of gauging characteristics of a thermoelectric element of each material.

ZT=(S²σ/κ)T Equation (2)

wherein S represents a Seebeck coefficient, σ represents electrical conductivity, κ represents thermal conductivity, and T represents an average temperature.

The thermoelectric effect is enhanced as a ZT value increases. An ideal thermoelectric material is a material having high electrical conductivity and poor thermal conductivity.

The thermal conductivity (κ) is decided as the sum of electronic thermal conductivity (κₑ) and lattice thermal conductivity (κ₁). In case of a metal, the κₑ is a dominant factor of thermal conductivity, and the thermal conductivity of the metal is general very large because free charge density is very high. In case of a nonconductor, thermal conductivity is mainly decided by the κ₁ because free charge density is very low. In case of a semiconductor, both the electronic thermal conductivity (κₑ) and the lattice thermal conductivity (κ₁) have an influence on the thermal conductivity (κ). In particular, in case of a metal, thermal conductivity and electric conductivity are expressed by “Wiedemann-Franz law”.

Kₑ/σT=L Equation (3)

Here, L is a proportional constant. As understood from the Equation (3), in case of a metal, a proportional relationship is established between thermal conductivity and electric conductivity. Therefore, it is difficult to artificially adjust a ZT value. In case of a semiconductor, in order to achieve a high ZT value, thermal conductivity of lattice is preferably designed to be smaller than thermal conductivity caused by free charges while maximally increasing electric conductivity.

When a temperature difference is applied to a thermoelectric material, a thermoelectric voltage is generated. If a load resistor is connected to a thermoelectric element, current flows. Use of the thermoelectric effect allows wasted heat to be converted to electric energy.

Power of a thermoelectric element must be high to be applied to real life. The maximum power is defined as follows:

P=(I_{sc}V_{oc})/4 Equation (4)

wherein V_{oc} represents an open voltage that indicates the maximum voltage when current does not flow to the thermoelectric element. I_{sc} represents short current.

A p-type thermoelectric material and an n-type thermoelectric material may be connected in series to maximize the function of the thermoelectric element. Conductive blocks are disposed below and above the p-type thermoelectric material and the n-type thermoelectric material, and a heater is mounted below the conductive block to be in contact with the conductive block. The p-type thermoelectric material and the n-type thermoelectric material have a hot junction and a cold junction. The heater applies a temperature difference to both ends of the p-type thermoelectric material and the n-type thermoelectric material to provide a hot junction. The other end of the p-type thermoelectric material and the n-type thermoelectric material is allowed to provide a cold junction by a cooling plate. The hot junction of the p-type thermoelectric material and the hot junction of the n-type thermoelectric material are electrically connected to each other, and the cold junction of the p-type thermoelectric material and the cold junction of the n-type thermoelectric material are electrically opened. A voltage between the cold junction of the p-type thermoelectric material and the cold junction of the n-type thermoelectric material is an open voltage. In addition, current flowing by electrically connecting the cold junction of the p-type thermoelectric material with the cold junction of the n-type thermoelectric material is short-circuit current I_{SC}. Power of the thermoelectric power generating element may be obtained with respect to a temperature difference dT.

### [Method for Producing Thermoelectric Material]

A Mn-doped Bi₂₋ₓMnₓSe₃ single crystal may be obtained by filling quartz ampoule with high-purity Bi, Mn, Se grains and heating the quart ampoule.

Specifically, a cleaning solution in which nitric acid and hydrochloric acid are mixed, acetone, and alcohol are provided to remove impurities of the quartz ampoule. The cleaning solution, the acetone, and the alcohol may sequentially clean the inside of the quartz ampoule, respectively. The impurities of the quartz ampoule may be removed by heating the quartz ampoule at a temperature from 900 to 1,000 degrees centigrade for a day.

Next, in order to achieve single-crystal growth of Bi₂₋ₓMnₓSe₃, the Bi, Mn, and Se grains are sequentially stored in the impurity-removed quartz ampoule according to a stoichiometric ratio. Accordingly, Se, Mn, and Bi are sequentially stacked on a bottom surface of the quartz ampoule. A single crystal having relatively small vacancy of Se may be formed using the stacked structure.

The Se and the Bi are disposed to surround the Mn. Thus, contact between the Mn and the quartz ampoule may be suppressed and reaction of the Mn to the quartz ampoule may be suppressed.

Se, Mn, and Bi used in the test will now be explained. Bi may have a purity of 99.999 percent, be needle-shaped grains, and have a length of 5 to 10 millimeters (mm). Se may have a purity of 99.999 percent, have a circular shape (where one side is flat and the other side is convex), and have a diameter of 5 mm and the maximum thickness of 1 mm. Mn may have a purity of 99.9 percent, have a shape of square whose one side has a length of 2 mm to 5 mm, and have a thickness of 1 mm.

A vacuum pump may exhaust the inside of the quartz ampoule to provide vacuum to the inside of the quart ampoule. A pressure of the quartz ampoule may be about 10⁻⁶ Torr. The puck is made of quartz and has a cylindrical shape. The puck has a height of about 0.7 mm and a diameter of 0.7 mm.

For the single-crystal growth, a furnace increased a temperature of the sample-stored quartz ampoule to 850 degrees centigrade over 12 hours. The furnace slowly decreases the temperature of the quartz ampoule to 620 degrees centigrade over 46 hours after keeping the quartz ampoule at a temperature of 850 degrees centigrade for an hour. Next, the quartz ampoule is taken out of the furnace while keeping the quartz ampoule at the temperature of 620 degrees centigrade. Next, the quartz ample is immersed in cooling water to be quenched. The produced Bi₂₋ₓMnₓSe₃ single crystal had a cleavage property.

### [Componential Analysis]

Mn-doped Bi₂₋ₓMnₓSe₃ single crystal was confirmed by performing an X-ray diffraction (XRD) test and an X-ray absorption spectroscopy (XAS) test. A lattice structure and a lattice constant of the Mn-doped Bi₂₋ₓMnₓSe₃ single crystal were calculated through the XRD test. A valence value and a doping ratio of the Mn-doped Bi₂₋ₓMnₓSe₃ single crystal were calculated through the XAS test.

A size of a sample subjected to the XRD test was about 5 mm×5 mm. Thickness of the sample was about 1 mm to about 2 mm. After measuring electrical properties of the sample, the XRD test and the XAS test were performed. A size of a sample subjected to the XAS test was about 3 mm×3 mm, and thickness of the sample was about 1 mm to about 2 mm.

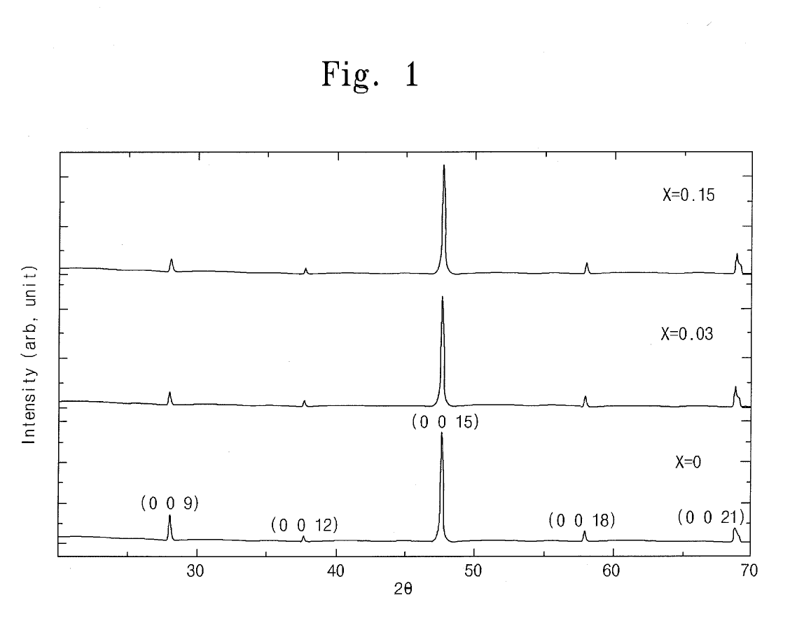

FIG. 1 shows XRD data of Mn-doped Bi₂₋ₓMnₓSe₃ single crystal according to an embodiment of the present invention.

Referring to FIG. 1, an XRD graph of Bi₂₋ₓMnₓSe₃ single crystal (x=0, x=0.03, x=0.15) is shown. Diffraction peaks may be represented as (a, b, c) using Miller index. According to a test result, all samples were aligned in a c-axis direction because all diffraction peaks were represented as (0, 0, n). Thus, all the samples (x=0, x=0.03, x=0.15) were single crystal and aligned in the x-axis direction. According to an analysis result of the XRD test, a c-axis lattice constant value was 28.64 angstroms (Å) with respect to hexagonal setting when Mn is not doped. In the sample (x=0.15), the c-axis lattice constant value is reduced to be 28.61 Å. The variation of the lattice constant value means that Mn is inserted instead of Bi. This is because an ionic radius of Mn is smaller than that of Bi. The XAS test was performed to obtain clearer evidence.

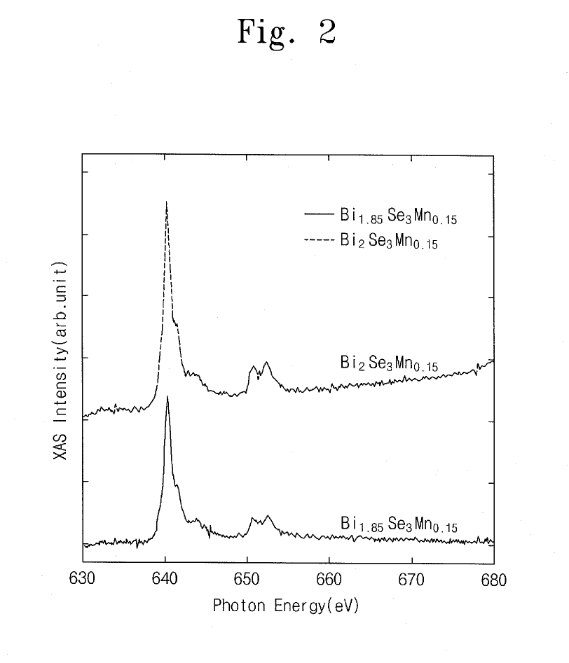

FIG. 2 shows XAS data of Mn-doped Bi₂₋ₓMnₓSe₃ single crystal (x=0.15) according to an embodiment of the present invention.

Referring to FIG. 2, absorption peaks indicate states of Mn L₃(2p_{3/2}) and L₂(2P_{1/2}), which means that a valence value of Mn is 2+. From the amplitude of XAS, a substitution rate of Mn was analyzed to be 0.09. The substitution rate (0.09) of the XAS was analyzed to be smaller than a stoichiometric ratio (0.15) used to produce a sample.

A smaller number of electrons generated at Mn²⁺ may compensate electrons generated at Bi³⁺. This may induce formation a p-type thermoelectric material through substitution of Mn.

According to a molecular formula of Bi₂Se₃, since three Se are present in a divalent state (Se²⁻) and two Bi are present in a positive trivalent state (Bi³⁺), they give and receive electrons to be an insulator. If Bi³⁺ is substituted by divalent Mn (Mn²⁺), three electrons are required but only two electrons are released. For this reason, an electron-deficient state may be established. That is, hole-carrier doping effect was produced. As a result, p-type conductivity was estimated. In other words, formation of a p-type thermoelectric material may be induced by Mn substitution.

Carrier type may be confirmed by measuring Hall effect and Seebeck coefficient.

TABLE (1)

| | | carrier density | carrier density |
|---|---|---|---|
| | | (cm⁻³) at | (cm⁻³) at |
| Material | carrier type | 10 Kelvin | 300 Kelvin |
| Bi2Se3 | n | 5.69 × 10\hat{ }19 | 5.83 × 10\hat{ }19 |
| Bi₂₋ₓMnₓSe₃ | n | 7.9 × 10\hat{ }8 | 8.04 × 10\hat{ }18 |
| (x = 0.03) | | | |
| Bi₂₋ₓMnₓSe₃ | p | 2.89 × 10\hat{ }18 | 2.66 × 10\hat{ }18 |
| (x = 0.05) | | | |
| Bi₂₋ₓMnₓSe₃ | p | 1.86 × 10\hat{ }18 | 2.09 × 10\hat{ }18 |
| (x = 0.09) | | | |
| Bi₂₋ₓMnₓSe₃ | p | 1.34 × 10\hat{ }18 | 1.63 × 10\hat{ }18 |
| (x = 0.15) | | | |

Referring to the Table (1), density of electron carrier of Mn-undoped Bi₂Se₃ (x=0) is 5.83×10¹⁹ cm⁻³ at 300 K. In case of Bi₂₋ₓMnₓSe₃ (x=0.03), density of electron carrier is 8.04×10¹⁸ cm⁻³ at 300 K.

On the other hand, in case of Bi₂₋ₓMnₓSe₃ (x=0.05), a carrier turned into a hole. Hole-carrier density decreases as doping concentration increases. In case of x=0.05, carrier density was 2.66×10¹⁸ cm⁻³. Change of the carrier type may occur between 0.03<x<0.05.

In order to confirm the change of the carrier type, Seebeck coefficient was measured in case of x=0.03 and in case of x=0.15. The Seebeck coefficient was compared with a result of measuring Hall resistance.

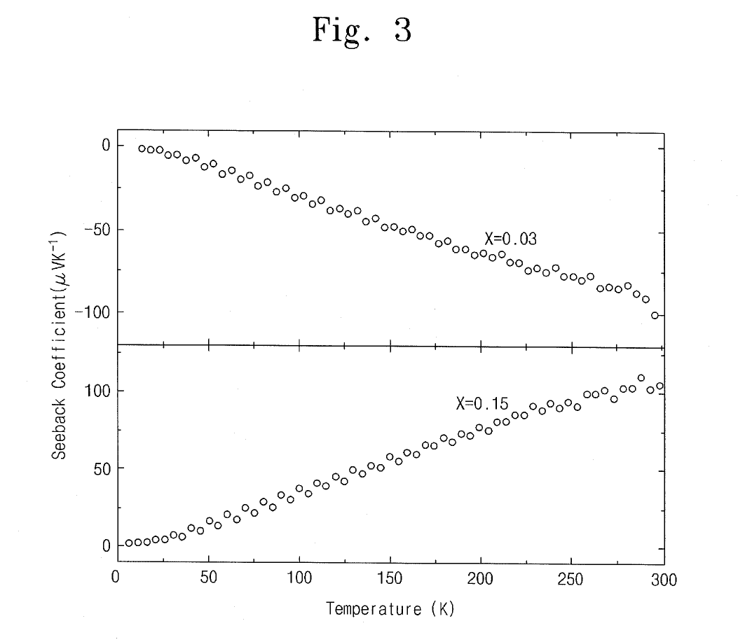

FIG. 3 shows data indicating a Seebeck coefficient of Mn-doped Bi₂₋ₓMnₓSe₃ single crystal (x=0.03, x=0.15) according to an embodiment of the present invention.

Referring to FIG. 3, when a doping rate is x=0.03, the Seebeck coefficient has a negative value which indicates a electron carrier. When a doping rate is x=0.15, the Seebeck coefficient has a positive value which indicates a hole carrier. This result matched a test result obtained by measuring Hall resistance.

In case of Bi₂₋ₓMnₓSe₃(x=0.03), the Seebeck coefficient has a negative value, and an absolute value of the Seebeck value increases linearly as temperature increases.

In case of Bi₂₋ₓMnₓSe₃ (x=0.15), the Seebeck coefficient has a positive value, and an absolute value of the Seebeck coefficient increases linearly as temperature increases.

When a doping rate is x=0.03 and x=0.15, the Seebeck coefficient has a constant value of about 100 μV/K at room temperature (300 K). As measured temperature increases, the Seebeck coefficient increases with a constant slope. Thus, Mn-doped Bi₂Se₃ may have thermoelectric application probability and may be used in a thermoelectric element.

Temperature-dependent resistivity (ρ) was measured to systemically analyze electrical properties of Mn doped Bi₂Se₃.

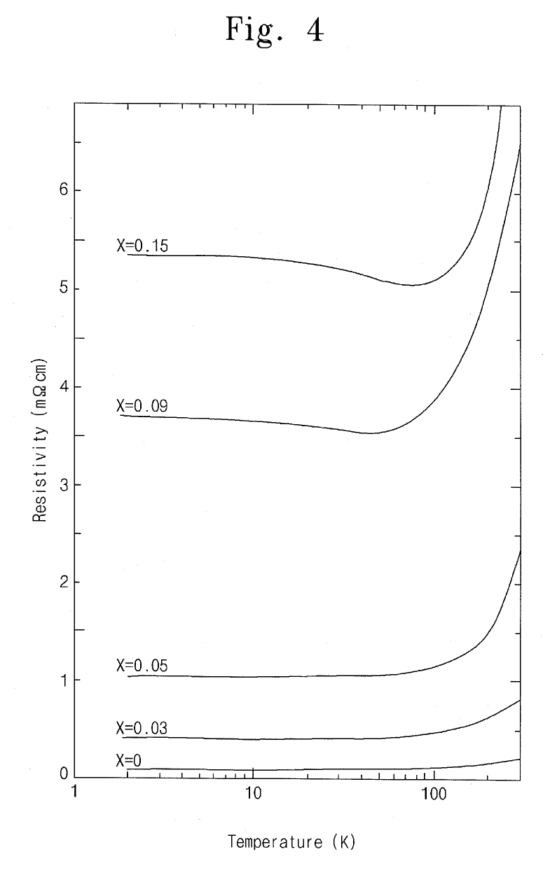

FIG. 4 shows data indicating temperature-dependent resistivity according to an embodiment of the present invention.

Referring to FIG. 4, electrical properties were measured using a quantum design physical property measurement system (PPMS). A size of a sample was about 5 mm×5 mm, and thickness of the sample was about 1 mm to 2 mm. A single-crystal sample was connected using a 4-probe method to measure electric resistance. The 4-probe method is a method of making a sample in the form of small rectangular parallelepiped and bonding four terminal lines thereonto. The bonding was done using a silver paste.

In the case that x=0.03, a gradient of temperature-dependent resistivity has a positive value at low temperature and room temperature. Therefore, Mn-doped Bi₂Se₃(x=0.03) shows a metallic behavior.

In the case that x=0.05, x=0.09, and x=0.15, a gradient of temperature-dependent resistivity has a positive value at room temperature. Therefore, Mn-doped Bi₂Se₃(x=0.05, x=0.09, and x=0.15) shows a metallic behavior.

However, a gradient of temperature-dependent resistivity has a negative value at low temperature less than about 100 Kelvin. Therefore, Mn-doped Bi₂Se₃(x=0.05, x=0.09, and x=0.15) shows a non-metallic behavior.

In case of a sample having a hole as a carrier, the characteristic supports the fact that Fermi level lies between the bulk conduction band minimum and the valence band maximum.

Resistivity may be in inverse proportion to density and mobility of a carrier. In the case that x=0.03, from well-known resistivity and density of a carrier, the mobility of an electron was analyzed to be 983 cm²V⁻¹s⁻¹ at room temperature. In the case that x=0.15, the mobility of a hole was analyzed to be 429 cm²V⁻¹s⁻¹ at room temperature. It is interpreted that the deceased mobility of a hole with high concentration of Mn is caused by scattering of Mn.

According to a conventional research result, when Bi₂Se₃ is doped with Ca or Mg, carrier type may be changed. In case of Mg, two electrons fill the 3s orbital. Mg produces 2+ ions. Thus, the 3s orbital of Mg²⁺ is made fully empty and the peripheral electron shell is to be a filled shell.

In case of Ca, two electrons fill the 4s orbital. Ca produces 2+ ions. Thus, the 4s orbital of Ca²⁺ is made fully empty and the peripheral electron shell is to be a filled shell.

However, an electron configuration of Mn is 3 d⁵ 4 s¹. Mn²⁺ constitute 3 d⁴ 4 s⁰. Thus, the peripheral electron shell is to be an unfilled shell. That is, since the peripheral electron shells of Mg and Ca are filled shells, there is no free mobile electron.

On the other hand, since the peripheral electron shell of Mn is an unfilled shell, there is a free electron. The free electron may decrease resistivity (ρ). Also the free electron may increase electron thermal conductivity (κₑ). However, since the electron thermal conductivity (κₑ) is smaller than phonon thermal conductivity (κₚₕ), increase of electron thermal conductivity is negligible. That is, if resistivity is reduced while thermal conductivity is almost unchanged, a high dimensionless figure of merit (ZT) may be obtained.

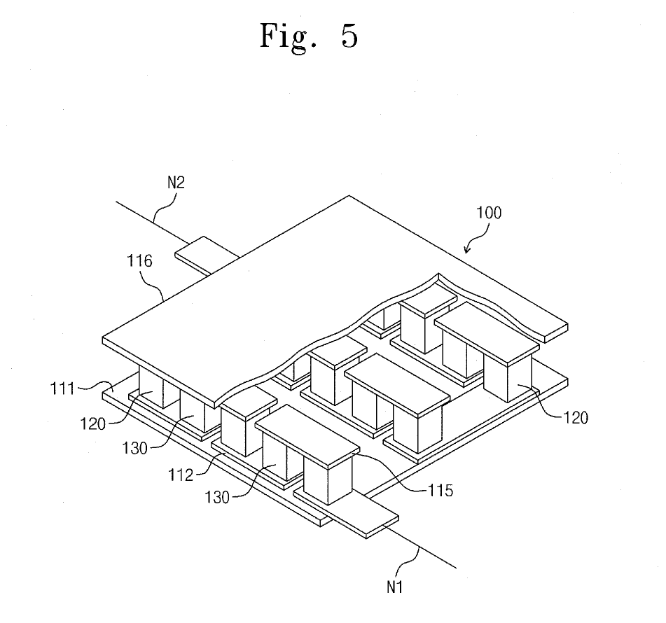

FIG. 5 shows a thermoelectric element 100 according to an embodiment of the present invention.

Referring to FIG. 5, the thermoelectric element 100 may include a first thermoelectric material 120 having a p-type carrier and a second thermoelectric material 130 having an n-type carrier. The first thermoelectric material 120 and the second thermoelectric material 130 are serially connected to each other to increase an open voltage.

The thermoelectric element 100 may be composed of single-crystal Bi₂₋ₓMnₓSe₃ and include a first thermoelectric material 120 having a p-type carrier and a second thermoelectric material 130 having an n-type carrier. In Bi₂₋ₓMnₓSe₃, 0.05<x<0.2 (x being a stoichiometric ratio provided to compound the first thermoelectric material 120). The first thermoelectric material 120 may be aligned with c-axis.

The second thermoelectric material 130 may be composed of Bi_{2-y}Mn_{y}Se having an n-type carrier. In Bi_{2-y}Mn_{y}Se, 0≦y≦0.05.

According to a modified embodiment of the present invention, the second thermoelectric material 130 is not limited to Bi_{2-y}Mn_{y}Se₃ having an n-type carrier and may be any one of thermoelectric materials having various n-type carriers. For example, the second thermoelectric material 130 may be Bi2Te3, CsBi4Te6, Zn4Sb3, or PbTe having an n-type carrier.

The thermoelectric element 100 may include a lower insulator 111, a lower electrode 112 disposed on the lower insulator 111, a first thermoelectric material 120 and a second thermoelectric material 130 disposed on the lower electrode 112, an upper electrode 115 disposed on the first thermoelectric material 120 and the second thermoelectric material 130, and an upper insulator 116 disposed on the upper electrode 115. The lower electrode 112 may electrically connect adjacent first and second thermoelectric materials in series to each other. The upper electrode 115 may electrically connect adjacent first and second thermoelectric materials in series to each other. Accordingly, the upper electrode 115 and the lower electrode 112 have the same structure but may be disposed after horizontally moving at a regular interval.

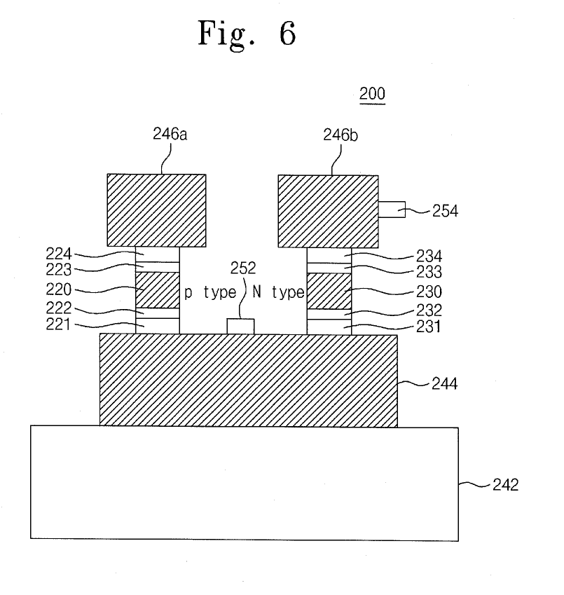

FIG. 6 shows a thermoelectric element according to an embodiment of the present invention.

Referring to FIG. 6, a thermoelectric element 200 was manufactured to inspect thermoelectric properties of Mn-doped Bi₂₋ₓMnₓSe₃ thermoelectric material. The thermoelectric element 200 may include a first thermoelectric material (p-type thermoelectric material) 220 and a second thermoelectric material (n-type thermoelectric material) 230 that are connected in series. The first thermoelectric material 220 may employ Mn-doped (x>0.05), and the second thermoelectric material 230 may employ Mn-doped Bi₂₋ₓMnₓSe₃ (x≧0.05).

Copper blocks were used as a heating block 244 and cooling blocks 246a and 246b. A heating unit 242 is disposed below the heating block 244. The heating unit 242 may be a hot plate. The heating block 244 had a rectangular shape and was manufactured of copper. The cooling blocks 246a and 246b include an n-type cooling block 246b and a p-type cooling block 246a.

The n-type thermoelectric material 230 and the p-type thermoelectric material 220 are in the form of thin plates, and both surfaces of the n-type thermoelectric material 230 are coated with electrodes 232 and 233 for achieving electrical contact. Each of the electrodes 232 and 233 may be gold (Au).

In addition, the both surfaces of the p-type thermoelectric material 220 are coated with electrodes 222 and 223 for achieving electrical contact. Each of the electrodes 222 and 223 may be gold (Au).

One surface of the n-type thermoelectric material 230 and one surface of the p-type thermoelectric material 220 are in contact with the heating block 244 through the electrodes 222 and 232 and silver paste 221 and 231. The other surface of the n-type thermoelectric material 230 is in contact with the n-type cooling block 246b through the electrode 233 and a silver paste 234. The other surface of the p-type thermoelectric material 220 is in contact with the p-type cooling block 246a through the electrode 223 and the silver paste 224.

The electrode 233 on the other surface of the n-type thermoelectric material 230 was electrically connected to the n-type cooling block 246b through a silver paste (product name: DOTITE D-500) 234.

The electrode 223 on the other surface of the p-type thermoelectric material 220 was electrically connected to the p-type cooling block 246a through a silver paste (product name: DOTITE D-500) 224.

Then, the silver paste 224 and 234 were baked at a temperature of about 100 degrees centigrade for an hour.

For electrical wire connection between the n-type cooling block 246b and the p-type cooling block 246a, a copper wire or a gold wire was connected through soldering and a silver paste. A first thermometer 252 was mounted on the heating block 244 to measure a temperature of the heating block 244. Second thermometers 254 were mounted on the p-type cooling block 246a and the n-type cooling block 246b to measure temperatures of the cooling blocks 246a and 246b, respectively.

A voltage was measured by a 2-probe method using a voltmeter (product name: KEITHLEY 2182A). Current was measured using an ammeter (product name: KEITHLEY 2636A). Resistance was measured using a multimeter.

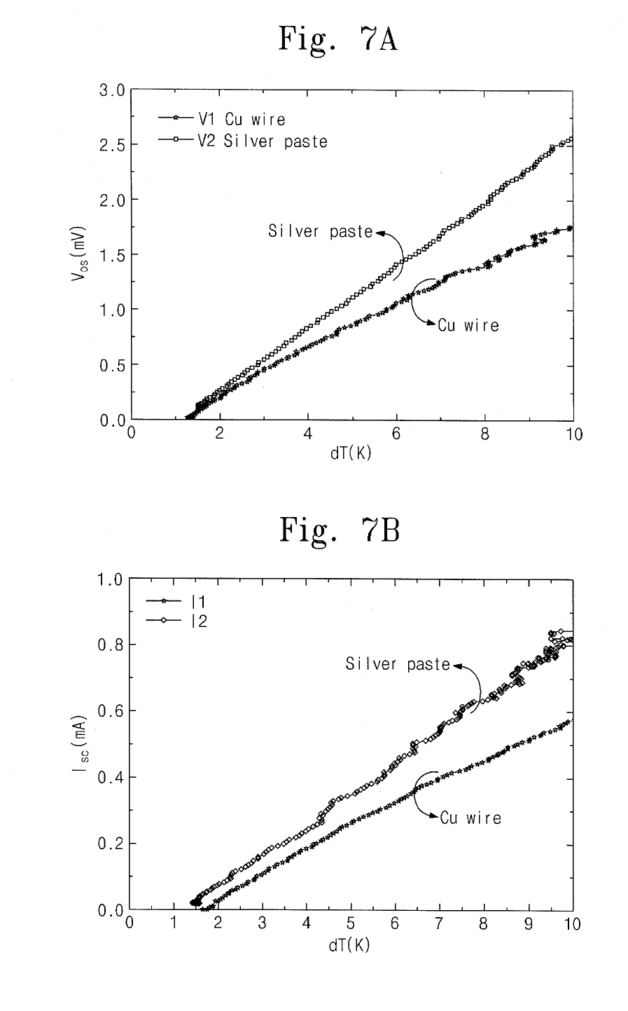

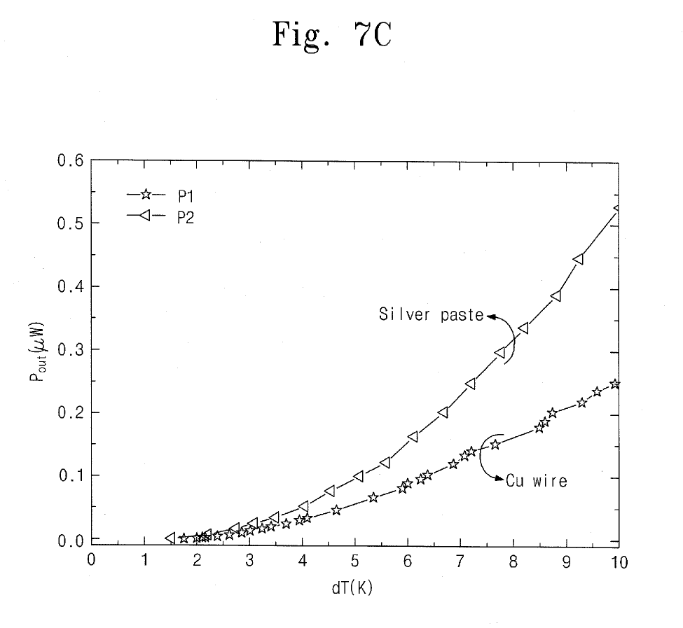

FIG. 7A shows data indicating an open voltage measured using the thermoelectric element in FIG. 6.

FIG. 7B shows data indicating short-circuit current measured using the thermoelectric element in FIG. 6.

FIG. 7C shows data indicating maximum power calculated using the thermoelectric element in FIG. 6.

Referring to FIG. 7A, a first thermoelectric material (p-type thermoelectric material) employed Bi₂₋ₓMnₓSe₃ (x=0.15), and a second thermoelectric material (n-type thermoelectric material) employed Bi₂₋ₓMnₓSe₃ (x=0.03).

In FIG. 7A, V1 represents data indicating an opening voltage, depending on a temperature difference (dT), connected using a copper (Cu) wire. Similar to the V1, V2 used a copper (Cu) wire but contact resistance was reduced using a silver paste.

Seebeck coefficient is a gradient of the voltage characteristic curve depending on a temperature difference. In the present test, the gradient was almost constant when a temperature difference (dT) between a heating block and a cooling block was 10 K.

Signs of Seebeck coefficients of two samples where Mn-doping concentrations (x) are 0.003 and 0.15 are different from each other. However, an absolute value of Seebeck coefficient is about 100 μV/K at room temperature. Accordingly, a difference of Seebeck coefficient of a thermoelectric element made in the present test may be about 200 μV/K at a temperature of 300 K.

When the temperature difference (dT) was 10 K, an open voltage showed value between 1.77 mV (V1) and 2.5 mV (V2).

Referring to FIG. 7B, I1 represents data indicating short-circuit current, depending on a temperature difference (dT), connected using a copper (Cu) wire. Similar to I1, I2 used a copper (Cu) wire but contact resistance was reduced using a silver paste.

When a temperature difference (dT) was 10 K, short-circuit current showed a value between 0.6 mA (I1) and 0.8 mA (I2).

Referring to FIG. 7C, P1 represents data indicating power, depending on a temperature difference (dT), connected using a copper (Cu) wire. Similar to P1, P2 used a copper (Cu) wire but contact resistance was reduced using a silver paste. If the contact resistance is reduced, short-circuit current flowing to a thermoelectric material may increase and power of the thermoelectric element may be enhanced.

Resistance may increase as a temperature of a heating block and an average temperature of a cooling block increase. The Mn-doped Bi₂Se₃ shows a metallic behavior at a temperature above room temperature.

Table (2) shows power obtained using an open voltage and short-circuit current. Theoretical resistance of the present invention was calculated using resistivity at room temperature, an area of a sample, and thickness of the sample. An area of a Bi₂₋ₓMnₓSe₃ (x=0.03) sample was 7.77×10⁻⁶ m², and thickness thereof was 0.69 mm. An area of a Bi₂₋ₓMnₓSe₃ (x=0.15) sample was 1.91×10⁻⁶ m², and thickness thereof was 0.79 mm.

TABLE (2)

| | | |
|---|---|---|
| Nextreme | Ours | Ours-ideal |

| | | | | | | |
|---|---|---|---|---|---|---|
| Vos/2 (V) | 3.6 | mV | 2.02 | mV | 2.02 | mV |
| R (Ohm) | 0.3 | Ohm | 2.36 | Ohm | 0.038 | Ohm |
| Pout (W) | 43.2 | μW | 1.73 | μW | 107.4 | μW |

There were shown an open voltage, resistance, and power of a power generator (HV56, manufactured by Nextreme Thermal Solutions, Inc.) that is available on the market. In addition, there were shown characteristics of a thermoelectric element having a structure in FIG. 6. Power of the thermoelectric element according to the present invention was estimated to be lower than that of the power generator manufactured by Nextreme Thermal Solutions, Inc. However, resistance according to the present invention is mainly due to contact resistance and may be reduced to theoretical resistance (0.038 Ohm). In this case, theoretical power (107.4 μW) according to the present invention was calculated to be higher than power (43.2 μW) of the power generator manufactured by Nextreme Thermal Solutions, Inc.

As described so far, a p-type thermoelectric conversion material according to an embodiment of the present invention showed a Seebeck coefficient of a few hundreds of μV/K at room temperature.

Although the present invention has been described in connection with the embodiment of the present invention illustrated in the accompanying drawings, it is not limited thereto. It will be apparent to those skilled in the art that various substitutions, modifications and changes may be made without departing from the scope and spirit of the present invention.

What is claimed is:

1. A thermoelectric conversion material which is composed of Bi₂₋ₓMnₓSe₃, is single-crystalline, and has a p-type carrier.

2. The thermoelectric conversion material as set forth in claim 1, wherein 0.05<x<0.2.

3. The thermoelectric conversion material as set forth in claim 1, which is aligned with c-axis.

4. A thermoelectric element comprising:
a first thermoelectric material which is composed of is composed of Bi₂₋ₓMnₓSe₃, is single-crystalline, and has a p-type carrier; and
a second thermoelectric material which is connected in series to the first thermoelectric material and has an n-type carrier.

5. The thermoelectric element as set forth in claim 4, wherein 0.05<x<0.2, and the first and second thermoelectric materials are aligned with c-axis.

6. The thermoelectric element as set forth in claim 4, wherein the second thermoelectric material is n-type and is composed of Bi_{2-y}Mn_{y}Se₃ (0≦y<0.05).

7. A method for producing a thermoelectric conversion material, comprising:
sequentially storing Bi, Mn, and Se powders in a quartz ampoule according to a stoichiometric ratio to sequentially store Bi, Mn, and Se;
heating the quartz ampoule storing Se, Mn, and Bi in a furnace to a temperature of 850 degrees centigrade over 12 hours;
keeping the quartz ampoule at a temperature of 850 degrees centigrade for an hour;
slowly cooling the quartz ampoule to a temperature of 620 degrees centigrade over 46 hours;
taking out the ampoule from the furnace while keeping the ampoule at the temperature of 620 degrees centigrade; and
immersing the quartz ampoule in cooling water to be quenched,
wherein the produced material is composed of Bi₂₋ₓMnₓSe₃, is single-crystalline, and has a p-type carrier.
